(19) United States
(12) Patent Application Publication
(10) Pub. No.: US 2021/0091090 A1
(43) Pub. Date: Mar. 25, 2021

(54) MEMORY ARRAY WITH CONTINUOUS DIFFUSION FOR BIT-CELLS AND SUPPORT CIRCUITRY

(71) Applicant: Microsoft Technology Licensing, LLC, Redmond, WA (US)

(72) Inventors: Jason Philip MARTZLOFF, Chapel Hill, NC (US); Tracey DELLAROVA, Wake Forest, NC (US); Gregory Scott CARTNEY, Durham, NC (US)

(21) Appl. No.: 16/575,954

(22) Filed: Sep. 19, 2019

(51) Int. Cl. H01L 27/11; H01L 29/10; H01L 29/78; H01L 27/02; G11C 11/419; G11C 11/412

(52) U.S. Cl. CPC H01L 27/1104; H01L 29/1079; H01L 27/1116; G11C 11/412; H01L 27/0207; G11C 11/419; H01L 29/7851

(57) ABSTRACT

Memory array circuitry includes a semiconductor substrate, a continuous diffusion in the semiconductor substrate, memory bit-cell circuitry, and support circuitry for the memory bit-cell circuitry. The continuous diffusion is a contiguous doped region of the semiconductor substrate. The memory bit-cell circuitry includes a bit-cell transistor formed on the continuous diffusion. The support circuitry includes a support transistor also formed on the continuous diffusion. By including both a bit-cell transistor and a support transistor on the same continuous diffusion, the necessary isolation between the bit-cell circuitry and the support circuitry may be reduced and the bit-cell transistor and the support transistor may have reduced length of diffusion (LOD) effects.

### FIELD OF THE DISCLOSURE

The present disclosure is related to memory arrays, and in particular to a memory array having memory bit-cells and support circuitry that share one or more continuous diffusions.

### BACKGROUND

Memory arrays include memory bit-cell circuitry and support circuitry for the memory bit-cell circuitry. Generally, the memory bit-cell circuitry and the support circuitry are on the same semiconductor substrate. As memory technology continues to evolve and the transistors used for memory bit-cells continue to shrink in size, the requirements for separating the transistors forming the memory bit-cell circuitry from the transistors forming the support circuitry have become more and more stringent, resulting in more and more wasted space on the semiconductor substrate forming the memory array.

FIG. 1 illustrates a portion of conventional memory array circuitry 10. The conventional memory array circuitry 10 includes a substrate 12, memory bit-cell circuitry 14, support circuitry 16, and a number of polysilicon runners 18 along a direction parallel to a Y-axis (illustrated in top left of figure). The memory bit-cell circuitry 14 includes a number of bit-cell diffusions 20 along a direction parallel to an X-axis perpendicular to the Y-axis (illustrated in top left of the figure) such that a number of the polysilicon runners 18 intersect the bit-cell diffusions 20. A number of bit-cell transistors 22 are formed in the memory bit-cell circuitry 14 on the bit-cell diffusions 20. Specifically, a first bit-cell transistor 22A is formed on a first bit-cell diffusion 20A between a second polysilicon runner 18B, a third polysilicon runner 18C, and a fourth polysilicon runner 18D. While not shown to avoid obscuring the drawing, the first bit-cell transistor 22A may be a fin field-effect transistor (FinFET) with one or more fins running perpendicular to and between the second polysilicon runner 18B, the third polysilicon runner 18C, and the fourth polysilicon runner 18D on the first bit-cell diffusion 20A such that the polysilicon runners 18 form the gate contact, drain contact, and source contact thereof.

A second bit-cell transistor 22B is formed on a second bit-cell diffusion 20B between the second polysilicon runner 18B, the third polysilicon runner 18C, and the fourth polysilicon runner 18D. While not shown, the second bit-cell transistor 22B may be FinFET with one or more fins running perpendicular to and between the second polysilicon runner 18B, the third polysilicon runner 18C, and the fourth polysilicon runner 18D on the second bit-cell diffusion 20B such that the polysilicon runners 18 form the gate contact, the drain contact, and the source contact thereof.

A third bit-cell transistor 22C is formed on a third bit-cell diffusion 20C between the second polysilicon runner 18B, the third polysilicon runner 18C, and the fourth polysilicon runner 18D. While not shown, the third bit-cell transistor 22C may be a FinFET with one or more fins running perpendicular to and between the second polysilicon runner 18B, the third polysilicon runner 18C, and the fourth polysilicon runner 18D on the third bit-cell diffusion 20C such that the polysilicon runners 18 form the gate contact, the drain contact, and the source contact thereof.

The support circuitry 16 includes a number of support diffusions 24 along a direction parallel to the X-axis such that a number of the polysilicon runners 18 intersect the support diffusions 24. A number of support transistors 26 are formed on the support diffusions 24. Specifically, a first support transistor 26A is formed on a first support diffusion 24A between a sixteenth polysilicon runner 18P, a seventeenth polysilicon runner 18Q, and an eighteenth polysilicon runner 18R. While not shown, the first support transistor 26A may be a FinFET with one or more fins running perpendicular and between the sixteenth polysilicon runner 18P, the seventeenth polysilicon runner 18Q, and the eighteenth polysilicon runner 18R such that the polysilicon runners 18 form the gate contact, drain contact, and source contact thereof.

A second support transistor 26B is formed on a second support diffusion 24B between the sixteenth polysilicon runner 18P, the seventeenth polysilicon runner 18Q, and the eighteenth polysilicon runner 18R. While not shown, the second support transistor 26B may be a FinFET with one or more fins running perpendicular and between the sixteenth polysilicon runner 18P, the seventeenth polysilicon runner 18Q, and the eighteenth polysilicon runner 18R such that the polysilicon runners 18 form the gate contact, the drain contact, and the source contact thereof.

A third support transistor 26C is formed on a third support diffusion 24C between the sixteenth polysilicon runner 18P, the seventeenth polysilicon runner 18Q, and the eighteenth polysilicon runner 18R. While not shown, the third support transistor 26C may be a FinFET with one or more fins running perpendicular to and between the sixteenth polysilicon runner 18P, the seventeenth polysilicon runner 18Q, and the eighteenth polysilicon runner 18R such that the polysilicon runners 18 form the gate contact, the drain contact, and the source contact thereof.

The particular position of the bit-cell transistors 22 and the support transistors 26 is merely exemplary for purposes of illustration, and in actual applications these transistors may be provided in different locations or span across additional polysilicon runners 18 to facilitate connections between the various transistors in higher level layers, which are not shown.

Notably, a diffusion break 28 separates the bit-cell diffusions 20 from the support diffusions 24. Among the reasons for this is the fact that the support transistors 26 are often a different size than the bit-cell transistors 22 and thus the bit-cell diffusions 20 are provided separately from the support diffusions 24, as illustrated by the different thicknesses of the bit-cell diffusions 20 and the support diffusions 24, where the thickness is along the direction of the Y-axis.

The different size of the bit-cell diffusions 20 and the support diffusions 24 may be due to a different number of fins used for the FinFETs (where thicker diffusions allow a larger number of fins).

The polysilicon runners 18, often referred to as gates, are divided into active gates 30 and dummy gates 32 as illustrated. Active gates 30 are those used to form a part of an active device (e.g., a bit-cell transistor 22 or a support transistor 26). Dummy gates 32 may be left floating or tied to a fixed potential (i.e., a predetermined voltage or ground). As shown, there are five dummy gates 32 (the fifth through ninth polysilicon runners, 18E through 18I) between the bit-cell transistors 22 and the diffusion break 28 as well as five dummy gates 32 (the eleventh through fifteenth polysilicon runners, 18K through 18O) between the support transistors 26 and the diffusion break 28. The tenth polysilicon runner 18J is also a dummy gate 32 such that there are eleven dummy gates 32 between the bit-cell transistors 22 and the support transistors 26. These dummy gates 32 are required to isolate the bit-cell transistors 22 from the support transistors 26 and ensure the proper functioning of each. However, these dummy gates 32, along with the diffusion break 28, take up a significant amount of area of the conventional memory array circuitry 10.

As the size of bit-cell transistors continues to shrink, the number of dummy transistors required for isolation purposes grows. Accordingly, the area of a semiconductor substrate providing memory array circuitry must either increase or the number of active devices in the memory array circuitry must be reduced, neither of which is desirable. Further, due to the diffusion break 28, the bit-cell transistors 22 and the support transistors 26 shown near the diffusion break 28 may suffer from length of diffusion (LOD) effects, which may diminish their performance. Accordingly, there is a need for improved memory array circuitry with increased active area and improved performance of bit-cell transistors and support transistors therein.

### SUMMARY

In one exemplary embodiment, memory array circuitry includes a semiconductor substrate, a continuous diffusion in the semiconductor substrate, memory bit-cell circuitry, and support circuitry for the memory bit-cell circuitry. The continuous diffusion is a contiguous doped region of the semiconductor substrate. The memory bit-cell circuitry includes a bit-cell transistor formed on the continuous diffusion. The support circuitry includes a support transistor also formed on the continuous diffusion. By including both a bit-cell transistor and a support transistor on the same continuous diffusion, the necessary isolation between the bit-cell circuitry and the support circuitry may be reduced and the bit-cell transistor and the support transistor may have reduced length of diffusion (LOD) effects.

In one exemplary embodiment, a method for manufacturing memory array circuitry includes providing a semiconductor substrate, providing a continuous diffusion in the semiconductor substrate, providing a bit-cell transistor on the continuous diffusion, and providing a support transistor on the continuous diffusion. The continuous diffusion is a contiguous doped region of the semiconductor substrate. The bit-cell transistor forms part of memory bit-cell circuitry. The support transistor forms part of a support circuitry for the memory bit-cell circuitry. By providing both a bit-cell transistor and a support transistor on the same continuous diffusion, the necessary isolation between the bit-cell circuitry and the support circuitry may be reduced and the bit-cell transistor and the support transistor may have reduced length of diffusion (LOD) effects.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a portion of conventional memory array circuitry.

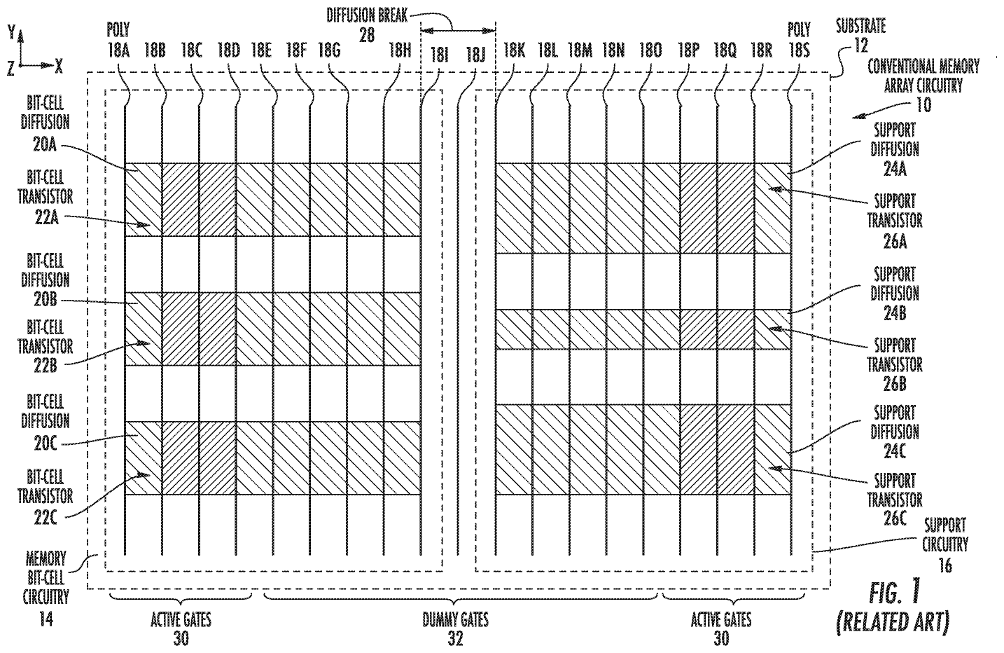

FIG. 2 illustrations a portion of memory array circuitry according to one embodiment of the present disclosure.

FIG. 3 illustrates a fin field-effect transistor (FinFET) according to one embodiment of the present disclosure.

FIG. 4 is a flow diagram illustrating a method for manufacturing memory array circuitry according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

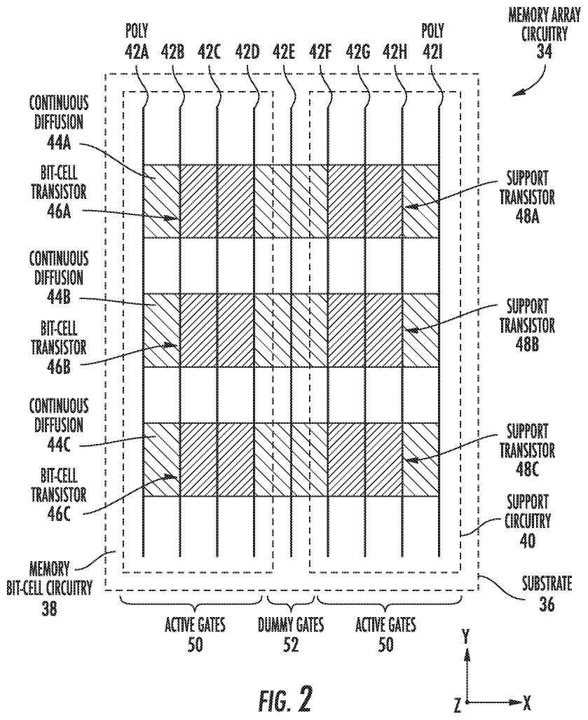

FIG. 2 illustrates a portion of memory array circuitry 34 according to one embodiment of the present disclosure. The memory array circuitry 34 includes a substrate 36, memory bit-cell circuitry 38, support circuitry 40, a number of polysilicon runners 42 along a direction parallel to a Y-axis (illustrated in bottom right of figure), and a number of continuous diffusions 44 along a direction parallel to an X-axis perpendicular to the Y-axis (illustrated in bottom right of figure) such that the polysilicon runners 42 intersect the continuous diffusions 44. The continuous diffusions 44 are contiguous doped regions in a semiconductor substrate over which transistors can be formed. The continuous diffusion 44 may be doped with an n-type dopant or a p-type dopant, depending on the type of transistor desired to be formed on the diffusion. The polysilicon runners 42 form conductive paths that are used to form devices as discussed below. Notably, the memory bit-cell circuitry 38 and the support circuitry 40 both use the continuous diffusions 44 to form transistors therein as discussed in detail below.

The memory bit-cell circuitry 38 includes a number of bit-cell transistors 46 forming one or more memory bit-cells, such as static random-access memory (SRAM) bit-cells (e.g., 6T SRAM bit-cells, 14T SRAM bit-cells). However, the present disclosure is not limited to SRAM. The principles of the present disclosure may be applied to any type of memory architecture, all of which are contemplated herein. The support circuitry 40 includes one or more support transistors 48 that are used to facilitate reading and writing to one or more memory bit-cells in the memory bit-cell circuitry 38. For example, the support circuitry 40 may be column support circuitry for a column of memory bit-cells in the memory bit-cell circuitry 38 and thus may be used to couple various memory bit-cells to supply voltages, ground, sense amplifiers, and the like. More specifically, the support circuitry 40 may include read and write multiplexers, write drives, read receivers, precharge and keeper circuitry, and input/output latches. The details of the support circuitry 40 may vary in different applications and will be readily appreciated by those skilled in the art. Those skilled in the art will readily appreciate that various circuit topologies exist for support circuitry for memory bit-cells, all of which are contemplated herein.

As discussed above, the memory bit-cell circuitry 38 includes the number of bit-cell transistors 46. For example, a first bit-cell transistor 46A is formed on a first continuous diffusion 44A between a third polysilicon runner 42B, a fourth polysilicon runner 42C, and a fifth polysilicon runner 42D. While not shown to avoid obscuring the drawings, the first bit-cell transistor 46A may be a fin field-effect transistor (FinFET) with one or more fins running perpendicular to and between the third polysilicon runner 42B, the fourth polysilicon runner 42C, and the fifth polysilicon runner 42D such that the polysilicon runners 42 form the gate contact, the drain contact, and the source contact thereof.

A second bit-cell transistor 46B is formed on a second continuous diffusion 44B between the third polysilicon runner 42B, the fourth polysilicon runner 42C, and the fifth polysilicon runner 42D. While not shown, the second bit-cell transistor 46B may be a FinFET with one or more fins running perpendicular to and between the third polysilicon runner 42B, the fourth polysilicon runner 42C, and the fifth polysilicon runner 42D such that the polysilicon runners 42 form the gate contact, the drain contact, and the source contact thereof.

A third bit-cell transistor 46C is formed on a third continuous diffusion 44C between the third polysilicon runner 42B, the fourth polysilicon runner 42C, and the fifth polysilicon runner 42D. While not shown, the third bit-cell transistor 46C may be a FinFET with one or more fins running perpendicular to and between the third polysilicon runner 42B, the fourth polysilicon runner 42C, and the fifth polysilicon runner 42D such that the polysilicon runners 42 form the gate contact, the drain contact, and the source contact thereof.

The particular position of the bit-cell transistors 46 is merely exemplary for purposes of illustration. In an actual application, the bit-cell transistors 46 may be offset from one another instead of provided in a column, or may be provided across any number of polysilicon runners 42. Those skilled in the art will readily appreciate that the bit-cell transistors 46 may be laid out to optimize a layout of the memory bit-cell circuitry 38 in higher-level layers in order to minimize a size of the memory array circuitry 34 and maximize a performance of the bit-cell transistors 46. Further, while only three bit-cell transistors 46 are shown for purposes of illustration, the memory bit-cell circuitry 38 may include any number of bit-cell transistors 46 without departing from the principles of the present disclosure. Generally, the memory array circuitry 34 will be tiled such that sections of the memory array circuitry 34 are repeated on all sides of the portion illustrated in FIG. 2.

As discussed above, the support circuitry 40 includes a number of support transistors 48. For, example, a first support transistor 48A is formed on the first continuous diffusion 44A between a sixth polysilicon runner 42F, a seventh polysilicon runner 42G, and an eighth polysilicon runner 42H. While not shown, the first support transistor 48A may be a FinFET with one or more fins running perpendicular to and between the sixth polysilicon runner 42F, the seventh polysilicon runner 42G, and the eighth polysilicon runner 42H such that the polysilicon runners 42 form the gate contact, the drain contact, and the source contact thereof.

A second support transistor 48B is formed on the second continuous diffusion 44B between the sixth polysilicon runner 42F, the seventh polysilicon runner 42G, and the eighth polysilicon runner 42H. While not shown, the second support transistor 48B may be a FinFET with fins running perpendicular to and between the sixth polysilicon runner 42F, the seventh polysilicon runner 42G, and the eighth polysilicon runner 42H such that the polysilicon runners 42 form the gate contact, the drain contact, and the source contact thereof.

A third support transistor 48C is formed on the third continuous diffusion 44C between the sixth polysilicon runner 42F, the seventh polysilicon runner 42G, and the eighth polysilicon runner 42H. While not shown, the third support transistor 48C may be a FinFET with fins running perpendicular to and between the sixth polysilicon runner 42F, the seventh polysilicon runner 42G, and the eighth polysilicon runner 42H such that the polysilicon runners 42 form the gate contact, the drain contact, and the source contact thereof.

The particular position of the support transistors 48 is merely exemplary for purposes of illustration. In actuality, the support transistors 48 may be offset from one another instead of provided in a column, or may be provided across any number of polysilicon runners 42. Those skilled in the art will readily appreciate that the support transistors 48 may be laid out to optimize a layout of the support circuitry 40 in higher-level layers in order to minimize a size of the memory array circuitry 34 and maximize a performance of the support transistors 48. Further, while only three support transistors 48 are shown for purposes of illustration, the support circuitry 40 may include any number of support transistors 48 without departing from the principles of the present disclosure. Generally, the memory array circuitry 34 will be tiled such that sections of the memory array circuitry 34 are repeated on all sides of the portion illustrated in FIG. 2.

The polysilicon runners 42, often referred to as gates, are divided into active gates 50 and dummy gates 52 as illustrated. Active gates are those used to form part of an active device (e.g., a bit-cell transistor 46 or a support transistor 48). Dummy gates 52 may be left floating or tied to a fixed potential (i.e., a predetermined voltage or ground). As shown, there is only one dummy gate 52 between the memory bit-cell circuitry 38 and the support circuitry 40. As discussed below, this is due to the relaxed isolation requirements between the bit-cell transistors 46 and the support transistors 48 due to their sharing of a continuous diffusion.

Notably, there is no diffusion break between the memory bit-cell circuitry 38 and the support circuitry 40. Rather, the bit-cell transistors 46 and the support transistors 48 share continuous diffusions 44 such that at least one bit-cell transistor 46 and at least one support transistor 48 share a contiguous diffusion 44. Using a continuous diffusion 44 for both bit-cell transistors 46 and support transistors 48 provides several benefits. First, the isolation necessary between the bit-cell transistors 46 and the support transistors 48 is reduced such that only one dummy gate 52 is required between the memory bit-cell circuitry 38 and the support circuitry 40. This is a massive decrease in size compared to the conventional memory array circuitry discussed above. Further, due to the use of continuous diffusions 44, length of diffusion (LOD) effects on both the bit-cell transistors 46 and the support transistors 48 are reduced, thereby improving the performance thereof.

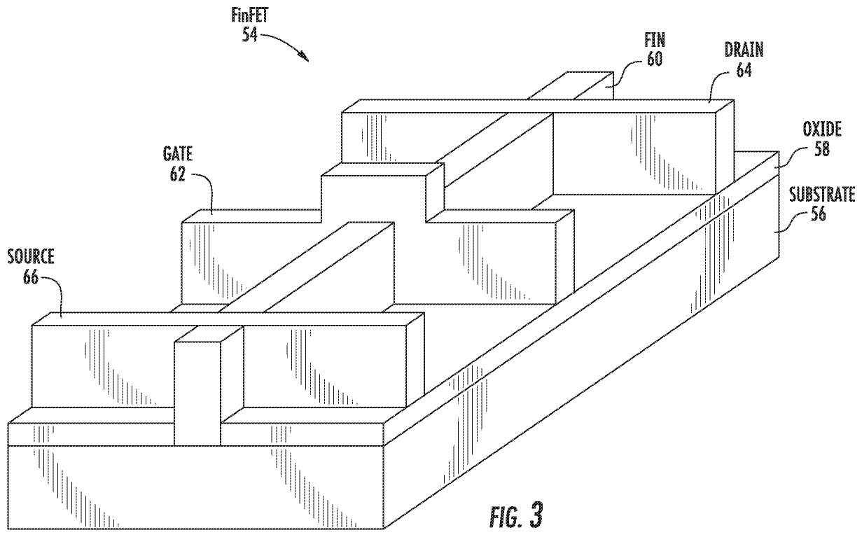

FIG. 3 illustrates a FinFET 54 according to one embodiment of the present disclosure. The FinFET 54 includes a substrate 56, an oxide layer 58 on the substrate 56, a fin 60, and a gate contact 62, a drain contact 64, and a source contact 66 intersecting the fin 60. The gate contact 62, the drain contact 64, and the source contact 66 may be formed from the polysilicon runners 42. As discussed above, the FinFET 54 is formed over a diffused region of the substrate 56 such that the fin 60 is formed from semiconductor material that is doped either n-type or p-type, depending on the desired type of FinFET. While only one fin 60 is shown, multiple fins may be provided in some cases. FIG. 3 is provided to illustrate one possible layout for the bit-cell transistors 46 and the support transistors 48. Those skilled in the art will appreciate that many different types of transistors, and in particular field-effect transistors (FETs) exists, and the bit-cell transistors 46 and the support transistors 48 may comprise any of these different types of transistors without departing from the principles of the present disclosure.

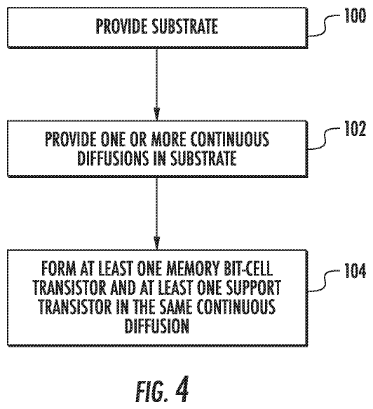

FIG. 4 is a flow diagram illustrating a method for manufacturing memory array circuitry according to one embodiment of the present disclosure. A substrate is provided (block 100). The substrate may be a semiconductor substrate suitable for forming memory array circuitry. One or more continuous diffusions are provided in the substrate (block 102). As discussed above, continuous diffusions are contiguous regions of doped semiconductor in the semiconductor substrate, and may be doped either n-type or p-type. At least one bit-cell transistor and at least one support transistor are formed in the same continuous diffusion (block 104). As discussed above, providing bit-cell transistors and support transistors such that they share the same continuous diffusions has several performance benefits such as a reduction in the size of isolation area required between memory bit-cell circuitry and support circuitry and an improvement in the performance of the bit-cell transistors and support transistors due to reduced LOD effects.

Those skilled in the art will recognize improvements and modifications to the preferred embodiments of the present disclosure. All such improvements and modifications are considered within the scope of the concepts disclosed herein and the claims that follow.

What is claimed is:

1. Memory array circuitry comprising:
a semiconductor substrate;
a continuous diffusion in the semiconductor substrate, the continuous diffusion comprising a contiguous doped region of the semiconductor substrate;
memory bit-cell circuitry comprising a bit-cell transistor formed on the continuous diffusion; and
support circuitry for the memory bit-cell circuitry, the support circuitry comprising a support transistor formed on the continuous diffusion.

2. The memory array circuitry of claim 1 wherein the bit-cell transistor and the support transistor are field-effect transistors (FETs).

3. The memory array circuitry of claim 2 wherein the bit-cell transistor and the support transistor are FinFETs.

4. The memory array circuitry of claim 1 wherein:
the bit-cell transistor comprises a bit-cell transistor gate;
the support transistor comprises a support transistor gate; and
the memory array circuitry further comprises a dummy gate between the bit-cell transistor gate and the support transistor gate.

5. The memory array circuitry of claim 4 wherein the dummy gate is the only dummy gate between the bit-cell transistor gate and the support transistor gate.

6. The memory array circuitry of claim 1 wherein the support circuitry for the memory bit-cell facilitates reading from and writing to the memory bit-cell circuitry.

7. The memory array circuitry of claim 6 wherein:
the bit-cell transistor comprises a bit-cell transistor gate;
the support transistor comprises a support transistor gate; and
the memory array circuitry further comprises a dummy gate between the bit-cell transistor gate and the support transistor gate.

8. The memory array circuitry of claim 7 wherein the dummy gate is the only dummy gate between the bit-cell transistor gate and the support transistor gate.

9. The memory array circuitry of claim 6 wherein the memory bit-cell circuitry comprises a static random-access memory (SRAM) bit-cell.

10. The memory array circuitry of claim 1 wherein the memory bit-cell circuitry comprises a static random-access memory (SRAM) bit-cell.

11. A method for manufacturing memory array circuitry comprising:
providing a semiconductor substrate;
providing a continuous diffusion in the semiconductor substrate, the continuous diffusion comprising a contiguous doped region of the semiconductor substrate;
providing a bit-cell transistor forming part of memory bit-cell circuitry on the continuous diffusion; and
providing a support transistor forming part of a support circuitry for the memory-bit cell circuitry on the continuous diffusion.

12. The method of claim 11 wherein the bit-cell transistor and the support transistor are field-effect transistors (FETs).

13. The method of claim 12 wherein the bit-cell transistor and the support transistor are FinFETs.

14. The method of claim 11 further comprising:
providing a bit-cell transistor gate, which runs over the continuous diffusion;
providing a support transistor gate, which runs over the continuous diffusion parallel to the bit-cell transistor gate; and
providing a dummy gate, which runs parallel to the bit-cell transistor gate and the support transistor gate and is between the bit-cell transistor gate and the support transistor gate.

15. The method of claim 14 wherein the dummy gate is the only dummy gate between the bit-cell transistor gate and the support transistor gate.

16. The method of claim 11 wherein the support circuitry for the memory bit-cell circuitry facilitates reading from and writing to the memory bit-cell circuitry.

17. The method of claim 16 further comprising:
providing a bit-cell transistor gate, which runs over the continuous diffusion;
providing a support transistor gate, which runs over the continuous diffusion parallel to the bit-cell transistor gate; and
providing a dummy gate, which runs parallel to the bit-cell transistor gate and the support transistor gate and is between the bit-cell transistor gate and the support transistor gate.

18. The method of claim 17 wherein the dummy gate is the only dummy gate between the bit-cell transistor gate and the support transistor gate.

19. The method of claim 16 wherein the support circuitry for the memory bit-cell circuitry facilitates reading from and writing to the memory bit-cell circuitry.

20. The method of claim 11 wherein the memory bit-cell circuitry comprises a static random-access memory (SRAM) memory cell.
